(19) United States
(12) Patent Application Publication
(10) Pub. No.: US 2025/0125182 A1
(43) Pub. Date: Apr. 17, 2025

(54) SUBSTRATE ROTATING APPARATUS, SUBSTRATE PROCESSING SYSTEM INCLUDING THE SAME, AND SUBSTRATE PROCESSING METHOD USING THE SAME

(71) Applicant: Samsung Electronics Co., Ltd., Suwon-si (KR)

(72) Inventors: HYUN HO CHOI, Suwon-si (KR); JAEHWAN KIM, Suwon-si (KR); YONG-HO BAEK, Suwon-si (KR); HYEOK-JIN JEONG, Suwon-si (KR); HO YUNG CHONG, Suwon-si (KR)

(21) Appl. No.: 18/628,404

(22) Filed: Apr. 5, 2024

(30) Foreign Application Priority Data
Oct. 11, 2023 (KR) 10-2023-0134860

(51) Int. Cl. H01L 21/687; H01L 21/673

(52) U.S. Cl. CPC H01L 21/68764; H01L 21/6732

(57) ABSTRACT

Disclosed are substrate rotating apparatuses, substrate processing systems, and substrate processing methods. The substrate rotating apparatus comprises vertically arranged stages and a rotary driver that turns the stages upside down. The stage includes a lower support assembly and an upper support assembly adjacent to the lower support assembly. The lower support assembly includes a lower support member having a lower support surface that supports one surface of a substrate. The upper support assembly includes upper support members. The upper support members are spaced apart from each other in a horizontal direction. A substrate placement space is between the upper support members. The upper support member includes an upper support surface that supports another surface of the substrate. The upper support surface is inclined toward the substrate placement space and makes an acute angle with the horizontal direction.

### CROSS-REFERENCE TO RELATED APPLICATION

This U.S. nonprovisional application claims priority under 35 U.S.C § 119 to Korean Patent Application No. 10-2023-0134860 filed on Oct. 11, 2023 in the Korean Intellectual Property Office, the disclosure of which is hereby incorporated by reference in its entirety.

### BACKGROUND

Aspects of the invention relate to a substrate rotating apparatus, a substrate processing system including the same, and a substrate processing method using the same, and more particularly, to substrate rotating apparatus capable of rotating a substrate to perform a process on the substrate turned upside down, a substrate processing system including the same, and a substrate processing method using the same.

A semiconductor device may be fabricated through various processes. For example, a semiconductor device may be manufactured by a deposition process, a photolithography process, an etching process, and a cleaning process that are performed on a substrate. Various kinds of substrate processing apparatus may be used for diverse processes of a substrate. In a deposition process, vertical furnace type batch facilities may be utilized for deposition. In batch facilities, a process may be performed on a plurality of vertically stacked substrates. For example, a gas may be introduced to batch facilities into which a plurality of substrates are inserted, and a deposition process may be performed on the plurality of substrates at the same time.

### SUMMARY

Some embodiments of the present invention provide a substrate rotating apparatus capable of preventing a substrate from being contaminated with particles, a substrate processing system including the same, and a substrate processing method using the same.

Some embodiments of the present inventive concepts provide a substrate rotating apparatus capable of turning a substrate upside down while protecting an active surface of the substrate, a substrate processing system including the same, and a substrate processing method using the same.

Some embodiments of the present inventive concepts provide a substrate rotating apparatus capable of simultaneously turning a plurality of substrates upside down, a substrate processing system including the same, and a substrate processing method using the same.

The object of the present inventive concepts is not limited to the mentioned above, and other objects which have not been mentioned above will be clearly understood to those skilled in the art from the following description.

According to some embodiments of the present inventive concepts, a substrate rotating apparatus may comprise: a plurality of stages that are vertically arranged; and a rotary driver configured to turn the plurality of stages upside down. Each of the plurality of stages may include: a lower support assembly including a lower support member having a lower support surface that supports one surface of a substrate; and an upper support assembly adjacent to the lower support assembly. The upper support assembly includes a plurality of upper support members. The lower support assembly may include a lower support member having a lower support surface that supports one surface of a substrate. The upper support assembly may include a plurality of upper support members. The plurality of upper support members may be spaced apart from each other in a horizontal direction. A substrate placement space may be between the plurality of upper support members. Each of the plurality of upper support members may include an upper support surface that supports another surface of the substrate. The upper support surface may be inclined toward the substrate placement space and may make an acute angle with the horizontal direction.

According to some embodiments of the present inventive concepts, a substrate processing system may comprise: substrate processing apparatus configured to process a substrate; a substrate rotating apparatus; and a transfer apparatus configured to transfer an overturned substrate to the substrate processing apparatus. The substrate rotating apparatus may include: a plurality of stages that are vertically arranged; and a rotary driver that turns the plurality of stage upside down.

According to some embodiments of the present inventive concepts, a substrate processing method may comprise: placing a substrate in a substrate rotating apparatus; turning the substrate upside down with the substrate rotating apparatus; with a transfer apparatus, unloading the substrate from the substrate rotating apparatus and placing the substrate in a substrate processing apparatus; and processing the substrate in the substrate processing apparatus. The step of processing the substrate may include performing a deposition process on the substrate.

Details of other example embodiments are included in the description and drawings.

### BRIEF DESCRIPTION OF DRAWINGS

FIG. 1 illustrates a plan view showing a substrate processing system according to some embodiments of the present inventive concepts.

FIG. 2 illustrates a cross-sectional view showing a substrate rotating apparatus according to some embodiments of the present inventive concepts.

FIG. 3 illustrates an enlarged cross-sectional view showing section X of FIG. 2.

FIG. 4 illustrates a plan view showing a substrate rotating apparatus according to some embodiments of the present inventive concepts.

FIG. 5 illustrates a cross-sectional view showing a substrate processing apparatus according to some embodiments of the present inventive concepts.

FIG. 6 illustrates an enlarged cross-sectional view partially showing a substrate processing apparatus according to some embodiments of the present inventive concepts.

FIG. 7 illustrates an enlarged cross-sectional view showing section Y of FIG. 6.

FIG. 8 illustrates a flow chart showing a substrate processing method according to some embodiments of the present inventive concepts.

FIGS. 9 to 23 illustrate diagrams showing a substrate processing method according to the flow chart of FIG. 8.

FIG. 24 illustrates a cross-sectional view showing a substrate rotating apparatus according to some embodiments of the present inventive concepts.

### DETAILED DESCRIPTION OF EMBODIMENTS

The following will now describe some embodiments of the present inventive concepts with reference to the accompanying drawings. Like reference numerals may indicate like components throughout the description.

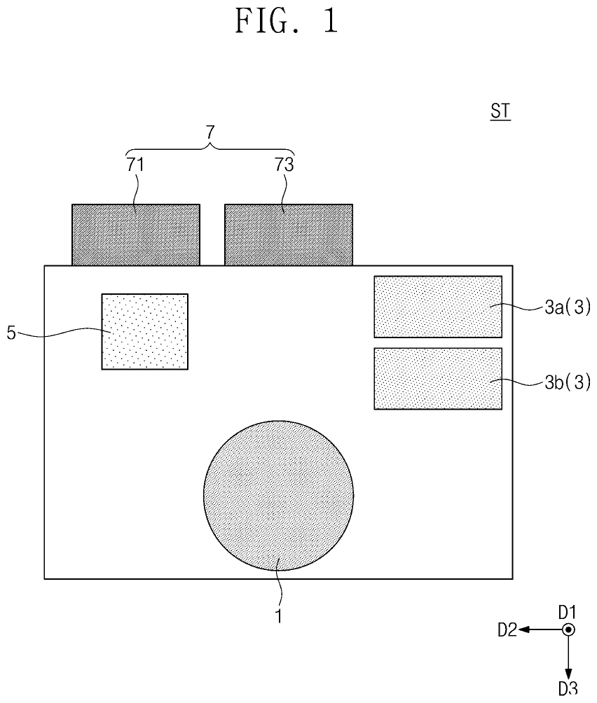

FIG. 1 illustrates a plan view showing a substrate processing system according to some embodiments of the present inventive concepts.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be a vertical direction or an upward direction. Each of the second direction D2 and the third direction D3 may be a horizontal direction.

Referring to FIG. 1, a substrate processing system ST may be provided. The substrate processing system ST may process a substrate. For example, the substrate processing system ST may perform a deposition process on a substrate. In addition, the substrate processing system ST may turn a substrate upside down. The “substrate” used in this description may be, for example, a starting substrate on which subsequent layers are to be formed during a semiconductor manufacturing process, such as a bulk silicon (Si) wafer, silicon on oxide (SOI) wafer, etc., but aspects of the invention are not limited thereto. Put another way, the “substrate” also may be an intermediate substrate, which is a semiconductor wafer in an intermediate stage of a manufacturing process. Accordingly, the present invention may be utilized to perform, for example, a deposition process at any stage prior to the creation of final semiconductor integrated circuits (IC) and to bond connection wires on the surface of a wafer, so that an intermediate substrate is encompassed by the “substrate.”

The substrate processing system ST may include a substrate processing apparatus 1, a substrate rotating apparatus 3, a transfer apparatus 5, and a loading port 7.

The substrate processing apparatus 1 may perform a deposition process on a substrate. The substrate processing apparatus 1 may perform a process on a plurality of substrates at the same time. For example, the substrate processing apparatus 1 may be a vertical furnace apparatus or a batch-type vertical furnace apparatus. The substrate processing apparatus 1 will be further discussed in detail below.

The substrate rotating apparatus 3 may rotate a substrate. For example, the substrate rotating apparatus 3 may be configured to turn a substrate upside down by rotating a substrate about an axis parallel to the horizontal direction. A substrate turned upside down in the substrate rotating apparatus 3 may be transferred to the substrate processing apparatus 1. A substrate, which is processed in the substrate processing apparatus 1 and then unloaded from the substrate processing apparatus into the substrate rotating apparatus, may be turned upside down again in the substrate rotating apparatus 3. The substrate rotating apparatus 3 may simultaneously turn a plurality of substrates upside down. The substrate rotating apparatus 3 may be provided in plural. For example, as shown in FIG. 1, there may be provided a first substrate rotating apparatus 3a and a second substrate rotating apparatus 3b. The present inventive concepts, however, are not limited thereto, and three or more substrate rotating apparatus 3 may be provided. One of the substrate rotating apparatuses 3 will be described below in the interest of convenience—it will be understood that such description may be applicable to all of the substrate rotating apparatuses 3.

The transfer apparatus 5 may transfer a substrate. For example, the transfer apparatus 5 may transfer a substrate between the loading port 7, the substrate rotating apparatus 3, and the substrate processing apparatus 1. The transfer apparatus 5 may include a traveling wheel, a substrate support arm, and a feeding motor. The transfer apparatus 5 may transfer a plurality of substrates at the same time. For example, the transfer apparatus 5 may transfer one to ten substrates at once. The present inventive concepts, however, are not limited thereto.

The loading port 7 may temporarily store a substrate. A substrate may be loaded on the loading port 7. When a substrate is loaded on the loading port 7, the transfer apparatus 5 may pick up and transfer a substrate to the substrate rotating apparatus 3 and/or the substrate processing apparatus 1. The loading port 7 may be provided in plural. For example, as shown in FIG. 1, a first loading port 71 and a second loading port 73 may be provided. The present inventive concepts, however, are not limited thereto.

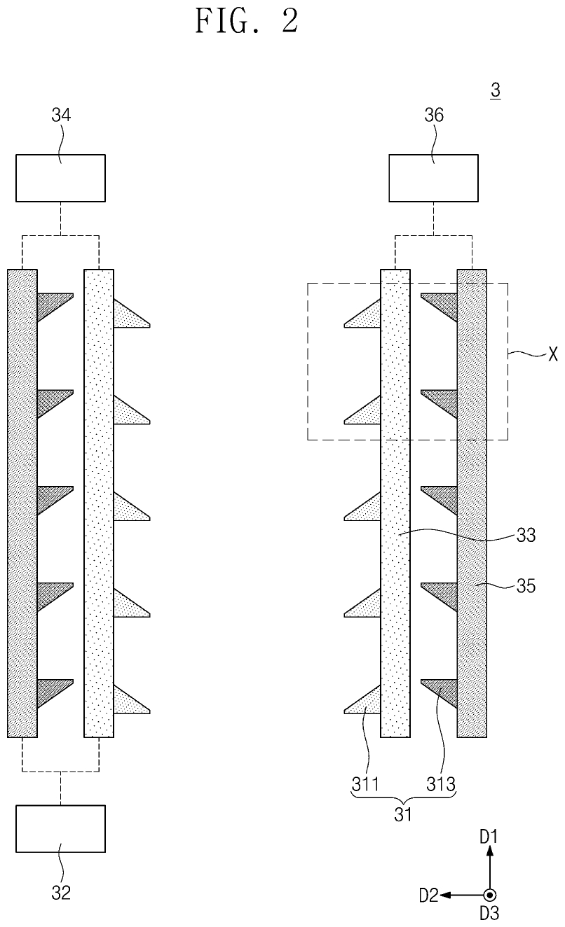

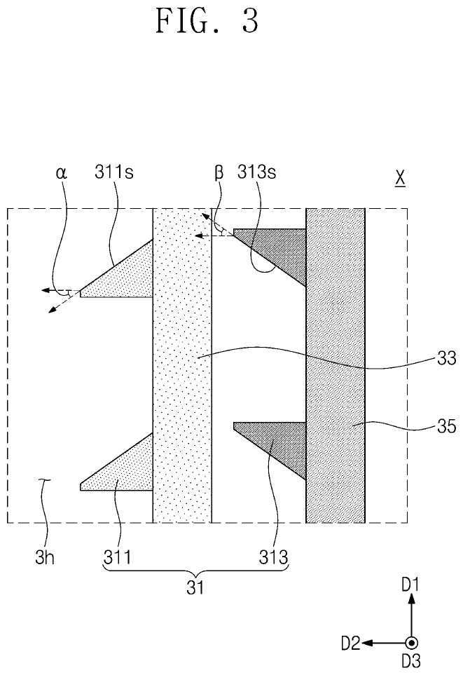

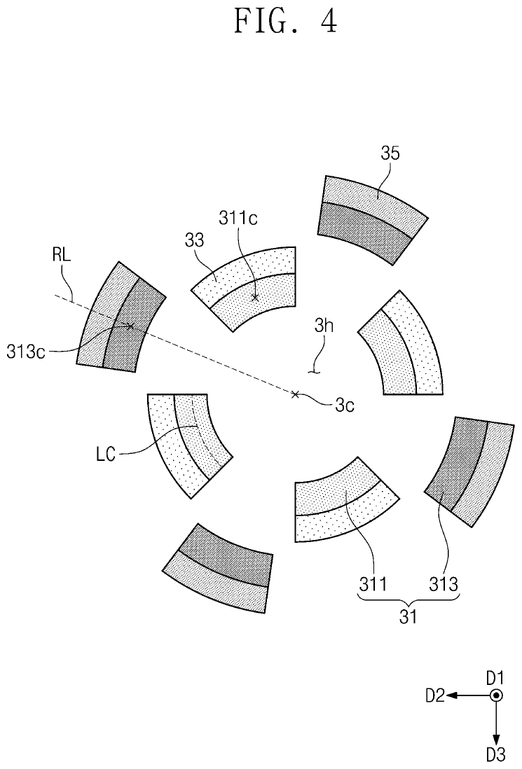

FIG. 2 illustrates a cross-sectional view showing a substrate rotating apparatus according to some embodiments of the present inventive concepts. FIG. 3 illustrates an enlarged cross-sectional view showing section X of FIG. 2. FIG. 4 illustrates a plan view showing a substrate rotating apparatus according to some embodiments of the present inventive concepts.

Referring to FIGS. 2 to 4, the substrate rotating apparatus 3 may include a stage 31, a first connection bar 33, a second connection bar 35, a rotary driver 32, a horizontal driver 34, and a vertical driver 36. The stage 31 may support a substrate. The stage 31 may include an upper support assembly and a lower support assembly.

The lower support assembly may include a lower support member 311. The lower support member 311 may support one surface of the substrate. The lower support member 311 may have a lower support surface 311s. The one surface of the substrate may be supported on the lower support surface 311s. The lower support surface 311s may be inclined at a first angle α with the horizontal direction. The first angle α may be an acute angle. For example, the first angle α may range from about 1° to about 60°, but the present inventive concepts are not limited thereto. The first angle α may be substantially the same as or similar to a second angle β. The lower support member 311 may extend a certain length in a circumferential direction while forming an arc shape.

The lower support member 311 may be provided in plural. The lower support assembly may include the plurality of lower support members 311. For example, as shown in FIG. 4, four lower support members 311 may be provided. The plurality of lower support members 311 may be disposed spaced apart from each other in the horizontal direction. For example, the plurality of lower support members 311 may be disposed spaced apart in the circumferential direction. Thus, a substrate placement space 3h may be defined between the plurality of lower support members 311.

The plurality of lower support members 311 may support one substrate. For example, a lower surface of the substrate may be disposed on the lower support surface 311s of each of the plurality of lower support members 311. As the lower support surface 311s makes an acute angle with the horizontal direction, a line contact may be provided between the substrate and the lower support surface 311s. For example, the substrate may be supported by a portion of the lower support surface 311s (i.e., a dashed line LC in FIG. 4) to make contact therebetween in a shape of a circular arc. A detailed description thereof will be further discussed below. Unless otherwise stated, one of the lower support members 311 will be discussed below.

The upper support assembly may include an upper support member 313. The upper support member 313 may support another surface of the substrate. For example, an upper surface (i.e., an opposite surface to the lower surface) of the substrate may contact the upper support surface 313s of each of the plurality of upper support members 313. The upper support member 313 may be disposed adjacent to the lower support member 311. The upper support member 313 may have an upper support surface 313s. The another surface of the substrate may be supported on the upper support surface 313s. The upper support surface 313s may be inclined toward the substrate placement space 3h. For example, the upper support surface 313s may make a second angle ß with the horizontal direction. The second angle ß may be an acute angle. For example, the second angle ß may range from about 1° to about 60°, but the present inventive concepts are not limited thereto. The upper support member 313 may extend a certain length in the circumferential direction while forming an arc shape.

The upper support member 313 may be provided in plural. The upper support assembly may include the plurality of upper support members 313. For example, as shown in FIG. 4, four upper support members 313 may be provided. The plurality of upper support members 313 may be disposed spaced apart from each other in the horizontal direction. The plurality of upper support members 313 may be disposed spaced apart from each other in the circumferential direction. Thus, the substrate placement space 3h may be defined between the plurality of upper support members 313. One substrate may be supported on the plurality of upper support members 313. For example, one substrate may be disposed on the upper support surface 313s of each of the plurality of upper support members 313. As the upper support surface 313s makes an acute angle with the horizontal direction, a line contact may be provided between the substrate and the upper support surface 313s. A detailed description thereof will be further discussed below. Unless otherwise stated, one of the upper support members 313 will be discussed below.

In one stage 31, the lower support member 311 and the upper support member 313 may not overlap each other. For example, when viewed in plan as shown in FIG. 4, each of the plurality of upper support members 313 may be disposed spaced apart in the horizontal direction from each of the plurality of lower support members 311 lest each upper support member 313 overlap each lower support member 311. For example, a center 311c of the lower support member 311 is not located on a radial line RL, which extends from a center 3c of the substrate placement space 3h to a corresponding center 313c of one of the upper support members 313 when respect to a plan view.

The stage 31 may be provided in plural. For example, two or ten stages 31 may be provided. Therefore, each of the lower and upper support assemblies may be provided in plural. The plurality of stages 31 may be vertically arranged. Therefore, a plurality of substrates may be vertically arranged in a state where the substrate is disposed on each of the plurality of stages 31. Unless otherwise stated, one of the stages 31 will be discussed below.

The first connection bar 33 may connect a plurality of lower support members 311 to each other. The first connection bar 33 may vertically extend. For example, the first connection bar 33 may vertically extend to connect to each other a plurality of lower support members 311 that are vertically arranged. The first connection bar 33 may be provided in plural. For example, as shown in FIG. 4, four first connection bars 33 may be provided. The plurality of first connection bars 33 may be disposed spaced apart from each other in the circumferential direction. One of the first connection bars 33 will be described below in the interest of convenience.

The second connection bar 35 may connect a plurality of upper support members 313 to each other. The second connection bar 35 may vertically extend. For example, the second connection bar 35 may vertically extend to connect to each other a plurality of upper support members 313 that are vertically arranged. The second connection bar 35 may be provided in plural. For example, as shown in FIG. 4, four second connection bars 35 may be provided. The plurality of second connection bars 35 may be disposed spaced apart from each other in the circumferential direction. one of the second connection bars 35 will be described below in the interest of convenience.

The rotary driver 32 may drive the stage 31 to rotate. For example, the rotary driver 32 may drive the stage 31 to rotate about an axis parallel to the horizontal direction, and thus the stage 31 may be turned upside down by about 180°. The rotary driver 32 may be connected to the stage 31. For example, the rotary driver 32 may be connected to the stage 31 through the first connection bar 33 and/or the second connection bar 35. Therefore, the rotary driver 32 may overturn a plurality of stages 31 at once (i.e., together at the same time). The rotary driver 32 may include an actuator such as a motor or a hydraulic device, but aspects of the present inventive concepts are not limited thereto.

The horizontal driver 34 may drive the lower support member 311 and/or the upper support member 313 to move in the horizontal direction. For example, the horizontal driver 34 may drive the lower support member 311 and/or the upper support member 313 to move in the horizontal direction and to approach or depart from a center 3c of the substrate placement space 3h. In some embodiments, the horizontal driver 34 may be connected through the first connection bar 33 and/or the second connection bar 35 to the lower support member 311 and/or the upper support member 313. The horizontal driver 34 may include an actuator such as a motor or a hydraulic device, but aspects of the present inventive concepts are not limited thereto.

The vertical driver 36 may drive the lower support member 311 and/or the upper support member 313 to vertically move. For example, the vertical driver 36 may drive the upper support member 313 to move in the vertical direction or vertically with respective to the lower support member 311. In some embodiments, the vertical driver 36 may be connected through the first connection bar 33 and/or the second connection bar 35 to the lower support member 311 and/or the upper support member 313. The vertical driver 36 may include an actuator such as a motor or a hydraulic device, but the present inventive concepts are not limited thereto.

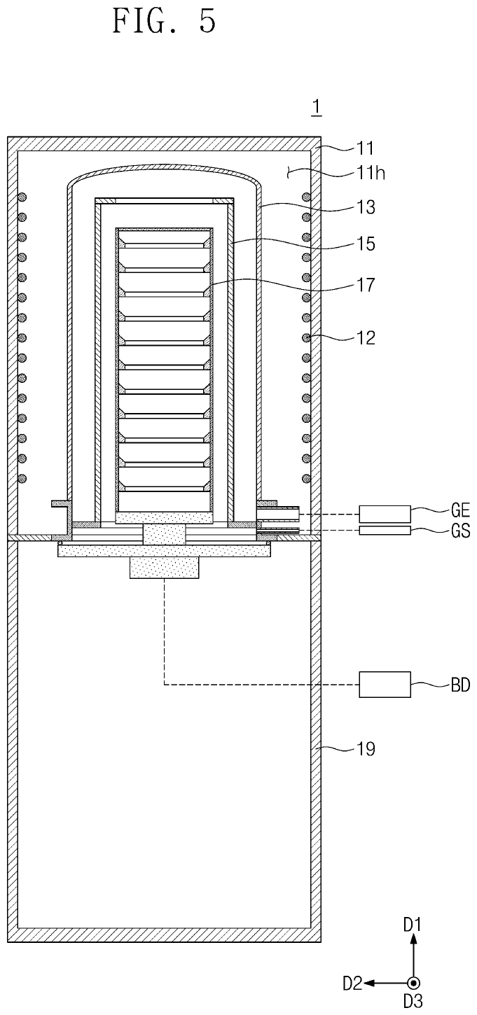

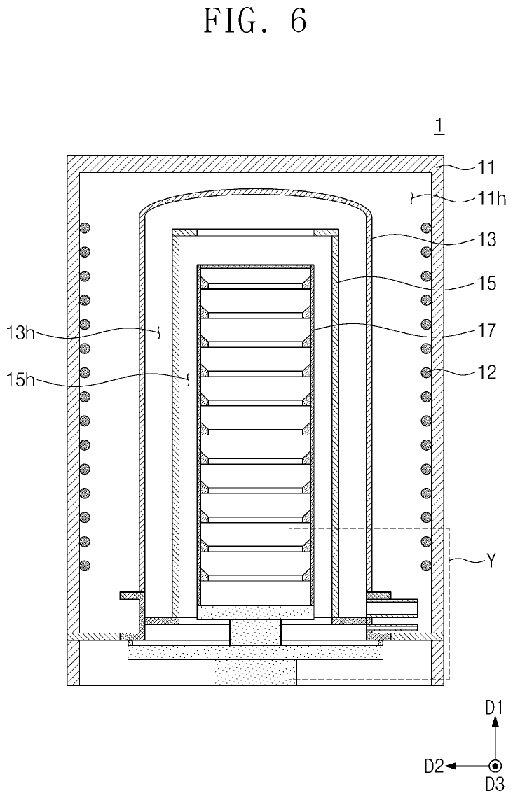

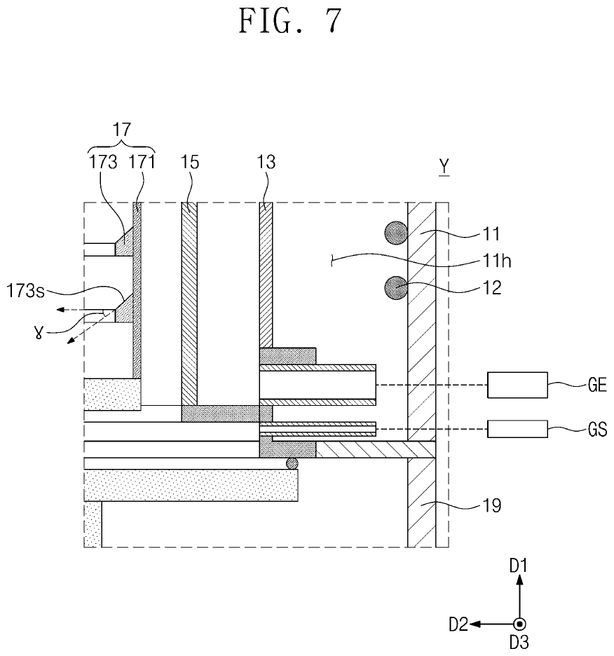

FIG. 5 illustrates a cross-sectional view showing a substrate processing apparatus according to some embodiments of the present inventive concepts. FIG. 6 illustrates an enlarged cross-sectional view partially showing a substrate processing apparatus according to some embodiments of the present inventive concepts. FIG. 7 illustrates an enlarged cross-sectional view showing section Y of FIG. 6.

Referring to FIGS. 5 to 7, the substrate processing apparatus 1 may include a process chamber 11, a lower chamber 19, a tube 15, an outer tube 13, a heater 12, a boat 17, a gas supply GS, a gas exhaust GE, and a boat driver BD. The process chamber 11 may provide an outer process space 11h. The tube 15, the outer tube 13, and the heater 12 may be positioned in the outer process space 11h. The process chamber 11 may separate the tube 15 from an external space. The lower chamber 19 may be positioned below the process chamber 11. The lower chamber 19 may support the process chamber 11. The boat 17 may be selectively disposed in the lower chamber 19.

The tube 15 may be positioned in the process chamber 11. The tube 15 may provide a process space 15h. The tube 15 may have a circular shape when viewed in plan, but the present inventive concepts are not limited thereto. The boat 17 may be selectively inserted into the tube 15. The outer tube 13 may be positioned between the tube 15 and the process chamber 11. The outer tube 13 may provide an intermediate space 13h. The intermediate space 13h may be connected to the gas exhaust GE. The heater 12 may include a coil. The heater 12 may heat the process space 15h. The heater 12 may be combined with, for example, an inner sidewall of the process chamber 11.

The boat 17 may be inserted into the tube 15. The boat 17 may support a substrate. A deposition process may be performed on the substrate disposed on the boat 17. The boat 17 may include a housing 171 and a process support member 173. The housing 171 may support the process support member 173. The substrate may be disposed on the process support member 173. The process support member 173 may include a process support surface 173s. The process support surface 173s may make a third angle γ with the horizontal direction. The third angle γ may be an acute angle. For example, the third angle γ may range from about 1° to about 60°, but the present inventive concepts are not limited thereto. As the process support surface 173s is inclined, a line contact may be provided between the process support surface 173s and the substrate disposed on the process support surface 173s. The boat 17 may support a plurality of substrates. The process support member 173 may be provided in plural. The plurality of process support members 173 may be disposed vertically spaced apart from each other. One of the process support members 173 will be described below in the interest of convenience.

The gas supply GS may be connected to the process space 15h. The gas supply GS may supply the process space 15h with gas. Therefore, a deposition process may be performed on a substrate disposed in the process space 15h. The gas exhaust GE may be connected to the intermediate space 13h. The gas exhaust GE may exhaust a gas from the process space 15h and/or the intermediate space 13h. The boat driver BD may be connected to the boat 17. The boat driver BD may drive the boat 17 to vertically move.

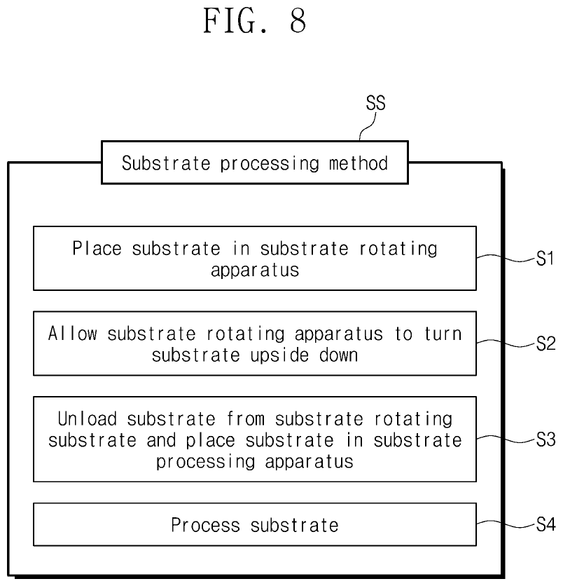

FIG. 8 illustrates a flow chart showing a substrate processing method according to some embodiments of the present inventive concepts.

Referring to FIG. 8, a substrate processing method SS may be provided. The substrate processing method SS may be a way of processing a substrate by using the substrate processing system ST discussed with reference to FIGS. 1 to 7. The substrate processing method SS may include placing a substrate in a substrate rotating apparatus (S1), allowing the substrate processing apparatus to turn the substrate upside down (S2), unloading the substrate from the substrate rotating apparatus and placing the substrate in a substrate processing apparatus (S3), and processing the substrate (S4).

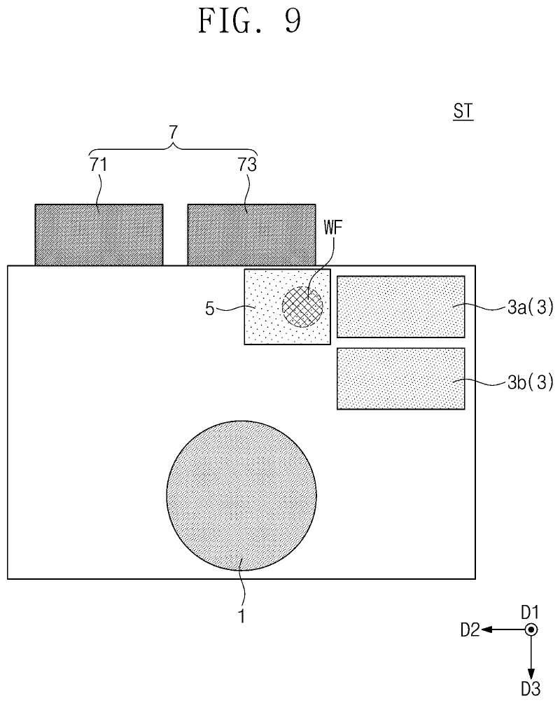

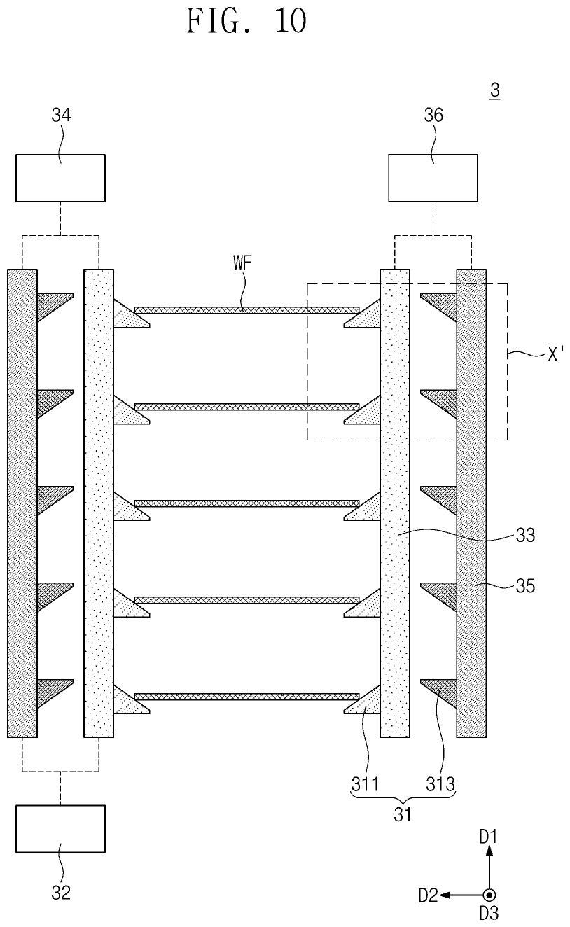

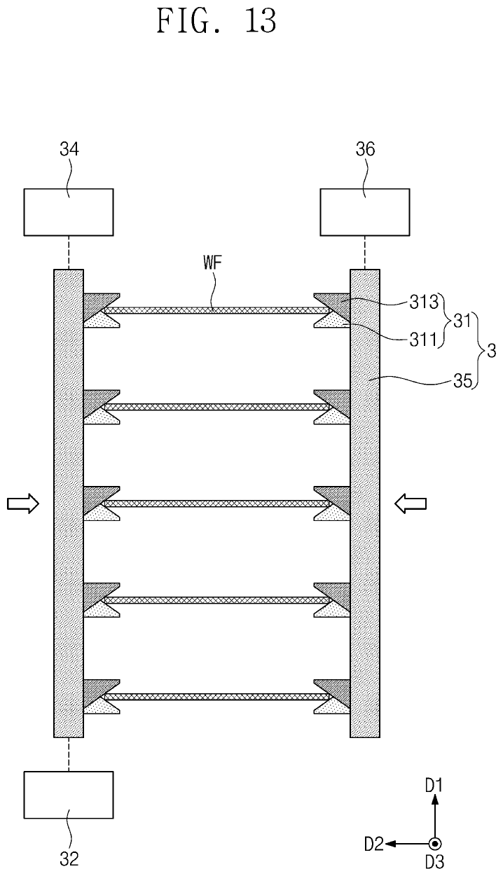

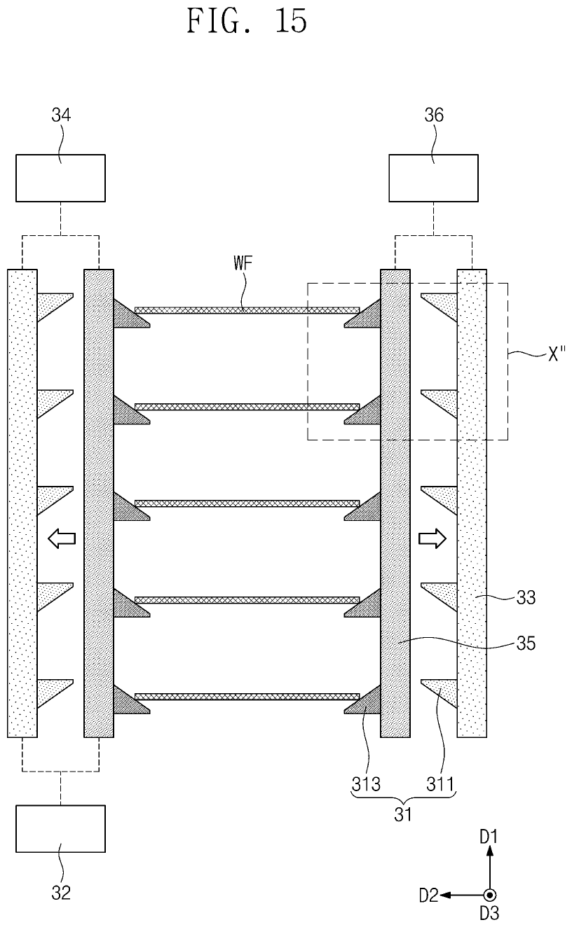

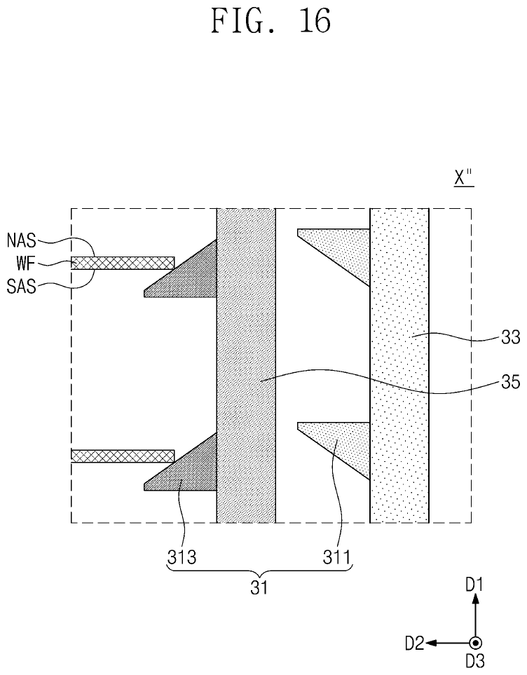

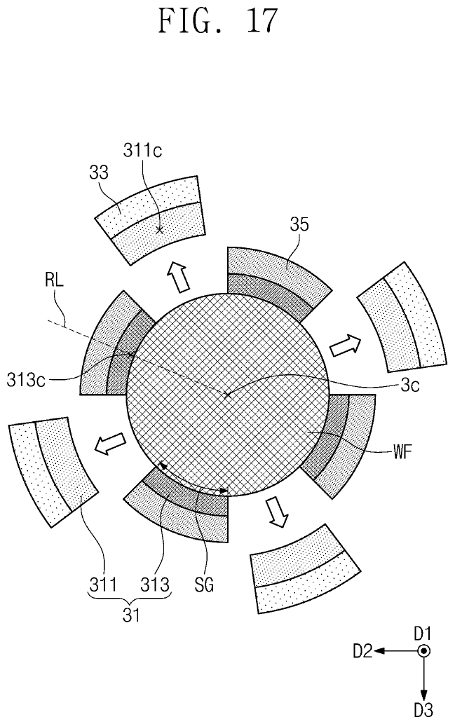

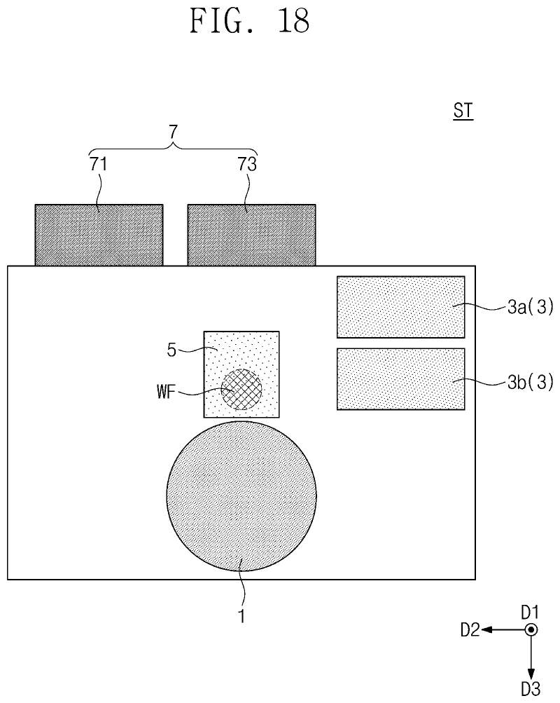

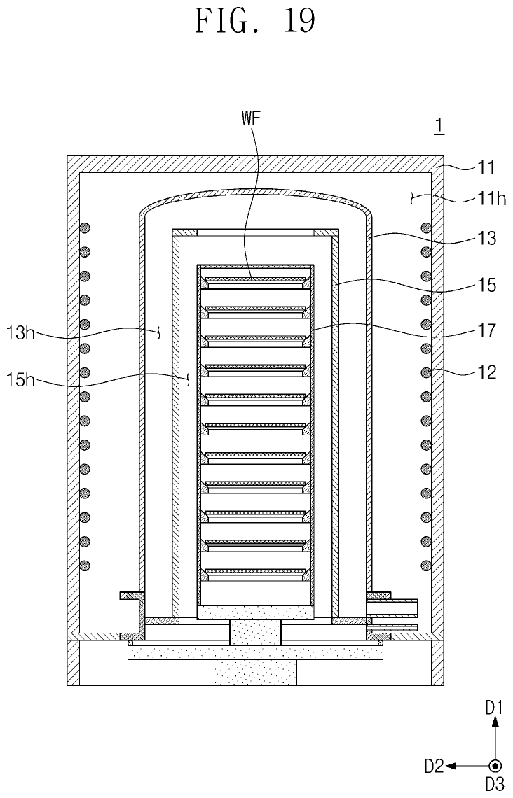

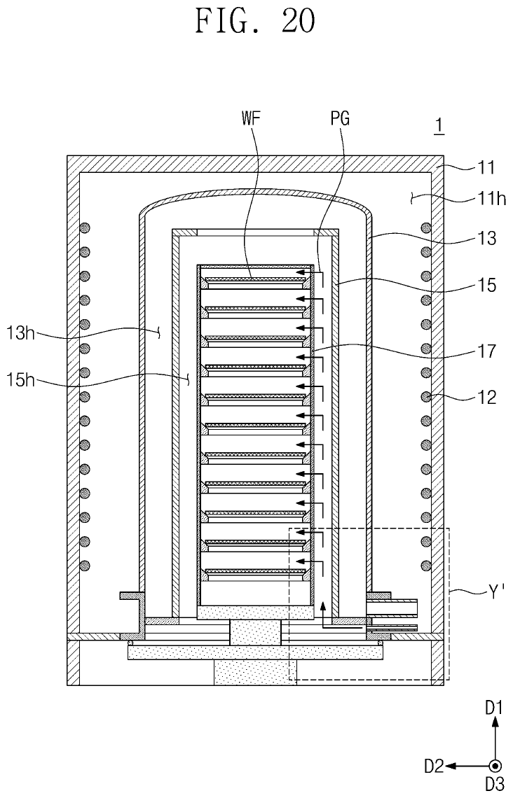

The substrate processing method SS of FIG. 8 will be discussed below with reference to FIGS. 9 to 23. FIGS. 9 to 23 illustrate diagrams showing a substrate processing method according to the flow chart of FIG. 8.

Referring to FIGS. 8, 9, 10, and 11, the substrate placement step S1 may include allowing the transfer apparatus 5 to pick up a substrate WF from the loading port 7 and to place the substrate WF in the substrate transfer apparatus 3. The substrate WF may be disposed on the stage 31. For example, the substrate WF may be disposed on the lower support member 311. The substrate WF disposed on the lower support member 311 may be in contact with the lower support surface 311s. For example, the substrate WF may be disposed on the lower support member 311 to achieve a line contact between the lower support surface 311s and an edge of a bottom surface of the substrate WF. In this step, the bottom surface of the substrate WF may be an inactive surface NAS. A top surface of the substrate WF may be an active surface SAS.

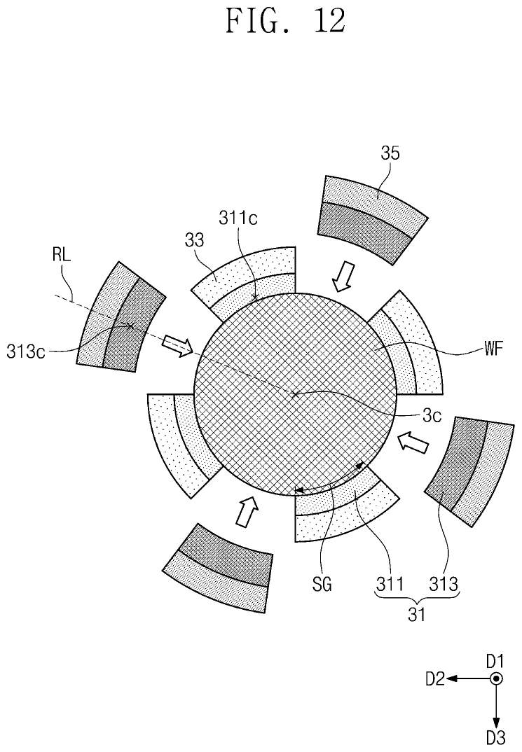

For example, a segment SG (shown in FIG. 12) of a circumferential edge of the substrate WF are supported by the lower support member 311. The substrate WF may include electronic devices formed thereon. Typically, the electronic devices may comprise integrated circuit layers, overlying and/or extending into one side of substrate WF, which forms the active surface SAS of the substrate WF. The active surface SAS within and on which transistors may be formed and typically interconnected by wiring formed thereon. The circuit layers are created by manufacturing processes including material deposition, patterning using photo masks and etching. The opposite side of substrate WF may be the inactive surface NAS. In this step, the bottom surface of the substrate WF may be the inactive surface NAS. A top surface of the substrate WF may be the active surface SAS.

In some embodiments, a plurality of substrates WF may be disposed in the substrate rotating apparatus 3. For example, the transfer apparatus 5 may transfer the plurality of substrates WF to the substrate rotating apparatus 3. The plurality of substrates WF may be correspondingly disposed on the plurality of stages 31. The plurality of substrates WF disposed in the substrate rotating apparatus 3 may be arranged vertically spaced apart from each other. One of the substrates WF will be discussed below in the interest of convenience.

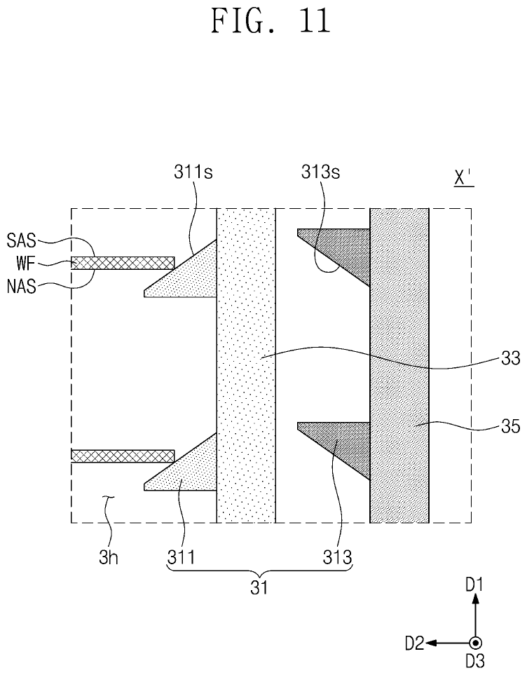

Referring to FIGS. 8, 12, and 13, the substrate overturn step S2 may include allowing the upper support member 313 to move inwardly. For example, the upper support member 313 may move toward the substrate WF, and the upper support member 313 and the substrate WF may contact each other. The upper support surface (see 313s of FIG. 11) of the upper support member 313 may be in contact with the top surface of the substrate WF. The substrate WF may contact all of the upper support member 313 and the lower support member 311. The substrate WF may be rigidly held (i.e., fixed) by being provided with downward and upward forces from the upper and lower support members 313 and 311. It is illustrated and described that the upper support member 313 moves only in the horizontal direction, but the present inventive concepts are not limited thereto. For example, the upper support member 313 may move in the vertical direction to contact the substrate WF. The movement of the upper support member 313 may be achieved by each of the horizontal driver 34 and the vertical driver 36.

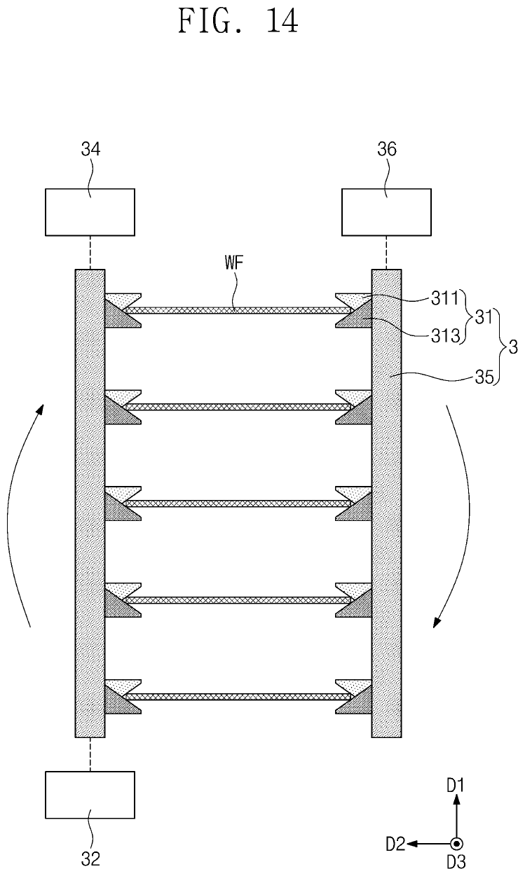

Referring to FIGS. 8 and 14, the substrate overturn step S2 may include overturning the stage 31 to turn the substrate WF upside down. For example, the stage 31 may be overturned in a state where the substrate WF is held by the upper support member 313 and the lower support member 311. Therefore, the substrate WF disposed on the stage 31 may also be turned upside down. The stage 31 may be overturned at about 180° about an axis parallel to the horizontal direction.

Referring to FIGS. 8, 15, 16, and 17, the substrate overturn step S2 may include allowing the lower support member 311 to move in the horizontal direction to depart from the substrate WF. For example, the lower support member 311 may move outwardly to release the contact with the substrate WF. Thus, only the upper support member 313 may contact the substrate WF. For example, a line contact may be provided between the upper support surface 313s of the upper support member 313 and the edge of the bottom surface of the substrate WF. For example, a segment SG of a circumferential edge of the substrate WF are supported by the upper support member 313. As the substrate WF is turned upside down, in this step, the bottom surface of the substrate WF may be the active surface SAS. The top surface of the substrate WF may be the inactive surface NAS. It is illustrated and described that the lower support member 311 moves only in the horizontal direction, but the present inventive concepts are not limited thereto. For example, the lower support member 311 may move in the vertical direction to depart from the substrate WF. The movement of the lower support member 311 may be achieved by each of the horizontal driver 34 and the vertical driver 36.

Referring to FIGS. 8, 18, and 19, the substrate unload and placement step S3 may include allowing the transfer apparatus 5 to unload the substrate WF from the substrate rotating apparatus 3 and to place the substrate WF in the substrate processing apparatus 1. The substrate WF unloaded from the substrate rotating apparatus 3 may be in the overturned state. For example, the bottom surface of the substrate WF released from the substrate rotating apparatus 3 may be the active surface. The substrate WF may be placed in the boat 17 of the substrate processing apparatus 1.

Referring to FIGS. 8, 20, and 21, the substrate process step S4 may include allowing the gas supply GS to supply the process space 15h with a process gas PG. The bottom surface of the substrate WF disposed on the process support member 173 of the boat 17 may be the active surface SAS. The process gas PG may be in contact with the bottom surface of the substrate WF, thereby forming a deposition layer on the bottom surface of the substrate WF. It is illustrated and described that the process gas PG is supplied at once below the boat 17, but the present inventive concepts are not limited thereto. For example, a nozzle extending in the vertical direction may further be provided to spray the process gas PG.

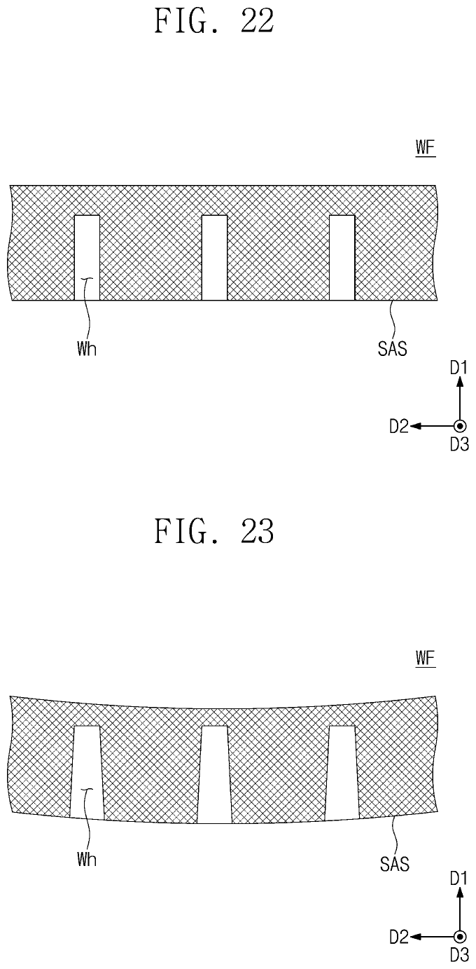

Referring to FIG. 22, there may be provided the substrate WF that is not warped. The bottom surface of the substrate WF of FIG. 22 may be the active surface SAS. In a state where the substrate WF is not warped, a hole Wh formed on the active surface SAS of the substrate WF may not be deformed.

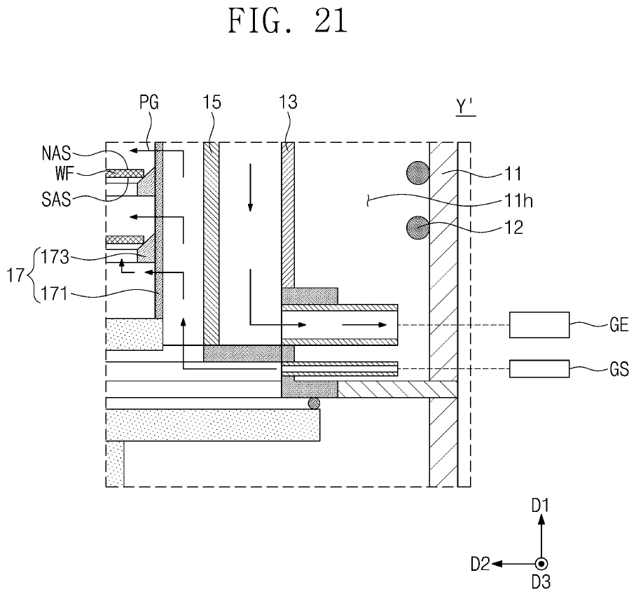

Referring to FIG. 23, there may be provided the substrate WF that sags down by gravity. In a state where an edge portion of the substrate WF is supported, the substrate WF may sink downwards in a central portion thereof and thus may be warped. In a state where the substrate WF is warped, the hole Wh of the substrate WF may be deformed. For example, a shape of the hole Wh may be changed to have a width at its upper end greater than a width at its lower end. In a state where the substrate WF is disposed to allow the active surface SAS to be the bottom surface, when a center of the substrate WF sags down by gravity, the hole Wh may have an increased entrance. Therefore, in a state where the substrate WF is disposed to allow the active surface SAS to be the bottom surface, a deposition process may be performed to cause the process gas (see PG of FIG. 21) to satisfactorily enter the hole Wh. Accordingly, a deposition process may be successfully performed on the substrate WF.

According to a substrate rotating apparatus, a substrate processing system including the same, and a substrate processing method using the same in accordance with some embodiments of the present inventive concepts, a process may be performed in a state where an active surface of a substrate is directed downwards, it may be possible to prevent contaminants such as particles from falling and sticking to the active surface of the substrate. Therefore, the substrate contamination may be prevented to increase a process yield.

According to a substrate rotating apparatus, a substrate processing system including the same, and a substrate processing method using the same in accordance with some embodiments of the present inventive concepts, as a lower support surface, an upper support surface, and a process support surface are inclined, there may be a reduction in contact area with a substrate. For example, a line contact may be provided between an edge of the substrate and each of the lower support surface, the upper support surface, and the process support surface. Therefore, even though the substrate is turned upside down to allow an active surface of the substrate to face downwards, the active surface may be prevented from being damaged caused by a support member for supporting the substrate.

According to a substrate rotating apparatus, a substrate processing system including the same, and a substrate processing method using the same in accordance with some embodiments of the present inventive concepts, a substrate may be turned upside down by using a substrate rotating apparatus that is separately provided. Thus, a transfer apparatus may not be needed to change a structure thereof. In addition, the substrate rotating apparatus may overturn a plurality of substrates at the same time. Accordingly, a prompt process may be accomplished. When two or more substrate rotating apparatuses are provided, a more prompt process may be achieved.

According to a substrate rotating apparatus, a substrate processing system including the same, and a substrate processing method using the same in accordance with some embodiments of the present inventive concepts, as an active surface of a substrate is a bottom surface, a process gas may be satisfactorily introduced into a hole of the substrate. As a result, a uniform deposition layer may be formed on the active surface of the substrate.

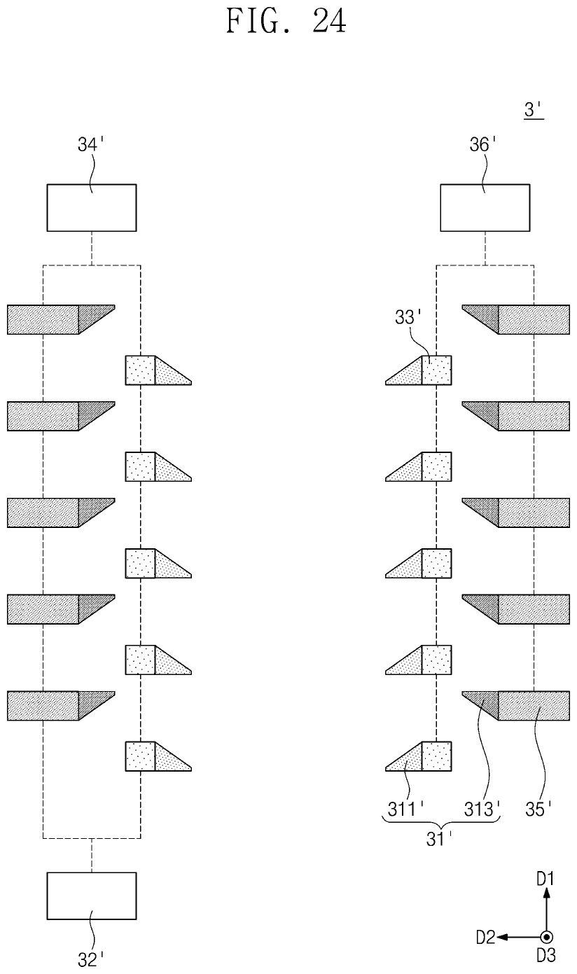

FIG. 24 illustrates a cross-sectional view showing a substrate rotating apparatus according to some embodiments of the present inventive concepts.

Hereinafter, omission will be made to avoid the description of components substantially the same as or similar to those discussed with reference to FIGS. 1 to 23.

Referring to FIG. 24, a substrate rotating apparatus 3′ may be provided. The substrate rotating apparatus 3′ may include a stage 31′, a first connection bar 33′, a second connection bar 35′, a rotary driver 32′, a horizontal driver 34′, and a vertical driver 36′.

Unlike that shown in FIGS. 2 and 3, the first connection bar 33′ of FIG. 24 may be connected only to one stage 31′. When the stage 31′ is provided in plural, the first connection bar 33′ may also be provided in plural. In addition, the second connection bar 35′ of FIG. 24 may be connected only to one stage 31′. When the stage 31′ is provided in plural, the second connection bar 35′ may also be provided in plural. Therefore, in a case of the horizontal movement of a lower support member 311′ and/or an upper support member 313′, it may be possible to prevent the movement interference caused by the first connection bar 33′ and/or the second connection bar 35′. Accordingly, the lower support member 311′ and an upper support member 313′ may have an increase in the degree of freedom of placement.

According to a substrate rotating apparatus, a substrate processing system including the same, and a substrate processing method using the same of the present inventive concepts, a substrate may be prevented from being contaminated due to contaminants such as particles.

According to a substrate rotating apparatus, a substrate processing system including the same, and a substrate processing method using the same of the present inventive concepts, a substrate may be turned upside down while protecting an active surface of the substrate.

According to a substrate rotating apparatus, a substrate processing system including the same, and a substrate processing method using the same of the present inventive concepts, a plurality of substrates may be overturned at once.

Effects of the present inventive concepts are not limited to the mentioned above, other effects which have not been mentioned above will be clearly understood to those skilled in the art from the following description.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A substrate rotating apparatus, comprising:
a plurality of stages that are vertically arranged; and
a rotary driver configured to turn the plurality of stages upside down,
wherein each of the plurality of stages includes:
a lower support assembly, the lower support assembly including a lower support member having a lower support surface that supports one surface of a substrate; and
an upper support assembly adjacent to the lower support assembly, the upper support assembly including a plurality of upper support members, wherein:
the plurality of upper support members are spaced apart from each other in a horizontal direction:
each of the plurality of upper support members includes an upper support surface that supports another surface of the substrate:
the upper support surface is inclined toward a substrate placement space and makes an acute angle with the horizontal direction; and
the substrate placement space is formed between the plurality of upper support members.

2. The substrate rotating apparatus of claim 1, wherein the lower support surface is inclined to make an acute angle with the horizontal direction.

3. The substrate rotating apparatus of claim 1, wherein each lower support assembly includes a plurality of lower support members that are spaced apart from each other in the horizontal direction.

4. The substrate rotating apparatus of claim 1, wherein the lower support member extends in a circumferential direction while forming an arc shape.

5. The substrate rotating apparatus of claim 1, further comprising:
a first connection bar that vertically extends to connect to each other a plurality of lower support assemblies provided on the plurality of stages; and
a second connection bar that vertically extends to connect to each other a plurality of upper support assemblies provided on the plurality of stages,
wherein the rotary driver is connected to the first connection bar and the second connection bar to allow the first connection bar, the second connection bar, and the plurality of stages to turn upside down at once.

6. The substrate rotating apparatus of claim 1, wherein the lower support member is spaced apart in the horizontal direction from each of the plurality of upper support members lest a center of the lower support member locates on a radial line, which is extended from a center of the substrate placement space into each of centers of the plurality of upper support members when viewed in plan.

7. The substrate rotating apparatus of claim 1, further comprising a horizontal driver configured to drive each of the plurality of upper support members to move in the horizontal direction and to depart from a center of the substrate placement space.

8. The substrate rotating apparatus of claim 1, further comprising a vertical driver configured to drive the upper support assembly to move vertically with respect to the lower support assembly.

9. The substrate rotating apparatus of claim 1, wherein the number of the plurality of stages is two to ten.

10. A substrate processing system, comprising:
a substrate processing apparatus configured to process a substrate;
a substrate rotating apparatus; and
a transfer apparatus configured to transfer an overturned substrate to the substrate processing apparatus,
wherein the substrate rotating apparatus includes:
a plurality of stages that are vertically arranged; and
a rotary driver that turns the plurality of stages upside down.

11. The substrate processing system of claim 10,
wherein each of the plurality of stages includes:
a lower support assembly and an upper support assembly, the upper support assembly is vertically movable,
wherein the lower support assembly includes a lower support member having a lower support surface that supports one surface of the substrate, and
wherein the upper support assembly includes an upper support member having an upper support surface that supports another surface of the substrate.

12. The substrate processing system of claim 11,
wherein the plurality of upper support members are spaced apart from each other in a horizontal direction, and a substrate placement space is between the plurality of upper support members.

13. The substrate processing system of claim 11, wherein the upper support surface is inclined to make an acute angle with a horizontal direction.

14. The substrate processing system of claim 10, wherein the substrate processing apparatus includes:
a process chamber;
a tube in the process chamber providing a process space; and
a boat inserted into the tube,
wherein the boat includes a plurality of substrate support members that are vertically spaced apart from each other.

15. A substrate processing method, comprising:
placing a substrate in a substrate rotating apparatus;
turning the substrate upside down with the substrate rotating apparatus;
with a transfer apparatus, unloading the substrate from the substrate rotating apparatus and placing the substrate in a substrate processing apparatus; and
processing the substrate in the substrate processing apparatus,
wherein processing the substrate includes performing a deposition process on the substrate.

16. The substrate processing method of claim 15, wherein the turning the substrate upside down with the substrate rotating apparatus includes turning upside down a plurality of substrates that are vertically arranged in the substrate rotating apparatus.

17. The substrate processing method of claim 15,
wherein the substrate rotating apparatus includes a stage, the stage including:
a lower support assembly, the lower support assembly including a lower support member having a lower support surface that supports one surface of the substrate; and
an upper support assembly adjacent to the lower support assembly, the upper support assembly including an upper support member having an upper support surface that supports another surface of the substrate, and
wherein placing the substrate in the substrate rotating apparatus includes placing the substrate on the lower support member to allow a bottom surface of the substrate to contact the lower support surface.

18. The substrate processing method of claim 17, wherein turning the substrate upside down with the substrate rotating apparatus includes:
contacting the upper support surface to a top surface of the substrate to allow the upper support member to fix the substrate; and
turning the stage upside down in a state where the substrate is fixed by the upper support member and the lower support member.

19. The substrate processing method of claim 18, wherein, when the upper support member fixes the substrate, the upper support surface is inclined to make an acute angle and a line contact is provided between the upper support surface and the top surface of the substrate.

20. The substrate processing method of claim 15, wherein processing the substrate includes performing the deposition process on a plurality of substrates that are vertically arranged in the substrate processing apparatus.
